(19) United States
(12) Patent Application Publication
(10) Pub. No.: US 2004/0139605 A1
(43) Pub. Date: Jul. 22, 2004

(54) Apparatus for checking terminal lock and method of checking terminal lock

(75) Inventors: Takashi Inada, Okayama (JP); Koji Kaneda, Okayama (JP); Yasushi Taniguchi, Okayama (JP); Masashi Fujino, Okayama (JP); Fusatoshi Araki, Okayama (JP); Toyokazu Machida, Okayama (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: YAZAKI CORPORATION, Tokyo (JP)

(21) Appl. No.: 10/749,414

(22) Filed: Jan. 2, 2004

(30) Foreign Application Priority Data
Jan. 8, 2003 (JP) 2003-001813

(51) Int. Cl. H01R 43/20; B23P 19/00; H05K 13/00

(52) U.S. Cl. 29/857; 29/854; 29/868; 29/747; 29/748

(57) ABSTRACT

An apparatus that can perform checking terminal lock in a connector housing securely are provided. The apparatus for checking terminal lock (1) includes a main body (8), a housing set portion (19) so as to be disposed in the main body (8) to move freely in a direction of inserting and extracting a terminal, and push means (6) for pushing the housing set portion (19) in the direction of inserting the terminal. On condition that a connector housing (2) is secured in the housing set portion (19) pushed by push means (6) and the terminal connected with a wire is inserted into the connector housing (2), terminal lock is checked by pulling the wire in a direction of extracting the terminal.

### BACKGROUND OF THE INVENTION

1. Field of the Invention

This invention relates to an apparatus for checking terminal lock and a method of checking terminal by means of pulling an electric wire after a terminal is inserted into a connector housing for checking terminal lock.

2. Description of the Related Art

According to a usual method of checking terminal lock, an electric wire with a terminal is pulled in an opposite direction of inserting the electric wire with the terminal for checking terminal lock after inserting the electric wire with the terminal into a terminal receiving section of a connector housing made of synthetic resin.

Checking terminal lock is for ascertaining whether or not a lock portion, such as a step portion or a hole, of the terminal is engaged securely with a flexible lock lance of the connector housing. When the terminal is not locked securely, the terminal is pulled out of the connector housing or moved in a direction of pulling. Thereby, defective lock is detected. In case of that the terminal is provided with a flexible locking piece to be engaged with the lock portion such as a step portion of the connector housing for terminal lock, defective lock is also detected by the same way.

If the terminal lock is defective in a product (at actual use), the terminal may be moved in the direction of extracting by vibration of a vehicle and contact of the terminal and a mating terminal may become incomplete or the contact may be lost. Thereby, it may cause a serious problem that power supply for car equipment or various auxiliary devices is stopped and operation of the equipment or devices is stopped.

The connector for a vehicle includes generally at least a connector housing and a plurality of terminals to be inserted into the connector housing. After electric wires with terminal are inserted respectively into terminal receiving sections of the connector housing by an operator hand, the terminal lock is checked by pulling the electric wire by hand at each insertion of the terminal or after insertion of all terminals. Terminals of connectors, for example by multi-kind and small quantity production and difficult to insert terminals with an automatic machine are inserted by hand.

Sub-wire-harness is structured by inserting terminals at one end of electric wires with a plurality of terminals into one connector housing, inserting terminals at both ends of the electric wires respectively into two connector housings or inserting terminals both by the former way and the later way. One wire harness (combined wires) is structured by binding a plurality of the sub-wire-harnesses with winding tapes, and assembling with a grommet and corrugated tubes.

The electric wire with terminals is inspected on its continuity in the sub-wire-harness or in the wire harness for judging quality of the continuity between connectors at both ends of the electric wire having terminals. By mounting one connector of the electric wire in a continuity test tool, connecting the other connector of the electric wire with a control unit for continuity test, and switching a circuit for each electric wire by the control unit for continuity test, the continuity of each electric wire with terminals is inspected. Thereby, the inspection results are indicated with a lamp or a buzzer. After the continuity test is accepted, the electric wires are finally assembled or packaged for shipping.

Objects to be Solved

According to the aforesaid usual method of checking terminal lock, checking terminal lock may be easily incomplete by widely varied pulling force of electric wires regarding operators. Thereby, too small pulling force may cause accepting incomplete terminal lock, or too large pulling force may cause deforming or breaking the lock lance of the connector housing or the locking piece of the terminal. The terminal for a signal line is small and the connector housing is also small correspondingly so that the lock lance may be easily broken. The continuity test of the connector is done after the terminal is checked on terminal lock, so that many processes for manufacturing the sub-wire-harness are required and efficiency of the manufacturing is low.

To overcome the above drawback, one object of this invention is to provide an apparatus for checking terminal lock and a method of checking terminal lock those can solve widely varied checking terminal lock so as to improve quality of checking terminal lock and prevent deforming or breaking of terminals and connector housings. Additionally, the other object of this invention is to provide the apparatus for checking terminal lock and the method of checking terminal lock those can inspect efficiently terminal lock and continuity of connectors.

### SUMMARY OF THE INVENTION

In order to attain the objects, an apparatus for checking terminal lock according to this invention, has a main body, a housing set portion for securing a connector housing, the housing set portion being disposed at the main body so as to move freely in a direction of inserting and extracting a terminal, and push means for pushing the housing set portion in the direction of inserting the terminal.

According to above structure, the connector housing secured in the housing set portion is moved together with the housing set portion against pushing force of push means. If the terminal is locked completely in the connector housing, the terminal is moved together with the connector housing and the pushing force as a checking force for checking terminal lock is loaded on the terminal. If the terminal is not locked completely, the terminal is moved from the connector housing in the direction of extracting terminals by the pushing force and the terminal lock is detected with an operator hand. This main body may be a base-plate for inspection or a base-plate having the other functions for inspecting.

The apparatus for checking terminal lock is further specified in the apparatus for checking terminal lock mentioned above by including detecting means for detecting whether or not pushing force of the push means reaches equal to a checking force of checking terminal lock.

According to above structure, an operator can recognize completion of checking terminal lock by a signal from the detecting means. Thereby, unnecessary further checking terminal lock is prevented.

The apparatus for checking terminal lock is further specified in the apparatus for checking terminal lock mentioned above that the push means is a coil spring.

According to above structure, the coil spring pushes the housing set portion in the direction of inserting terminals, and electric wires are pulled in the direction of extracting terminals against the pushing force of the coil spring. The terminal is pulled gradually in accordance with spring travel of the coil spring so that a force is not suddenly loaded on the terminal and the connector housing.

The apparatus for checking terminal lock is further specified in the apparatus for checking terminal lock mentioned above by including a stopper supporting the coil spring at one end of the stopper and being fixed on the main body at the other end of the stopper.

According to above structure, when the electric wire is pulled, the coil spring is compressed between the stopper and the housing set portion and the housing set portion is moved in the direction of extracting terminals against the stopper. The housing set portion is supported on the main body through the coil spring by the stopper so as to move freely in the direction of extracting terminals.

The apparatus for checking terminal lock is further specified in the apparatus for checking terminal lock mentioned above by comprising a guide member for guiding the housing set portion in the direction of inserting and extracting the terminal.

According to above structure, the housing set portion is slid smoothly in the direction of inserting and extracting the terminal so as to be positioned along the guide member.

The apparatus for checking terminal lock is further specified in the apparatus for checking terminal lock mentioned above by including a contact probe for testing continuity of the terminal at the main body.

According to above structure, checking terminal lock and continuity test of the electric wire with terminals can be performed efficiently in short time by one apparatus.

The apparatus for checking terminal lock is further specified in the apparatus for checking terminal lock mentioned above by including a lighting device provided at the main body for guiding the insertion of the terminal into a terminal receiving section of the connector housing.

According to above structure, checking terminal lock, continuity test of the electric wire with terminals and guiding the insertion of the terminal can be performed efficiently in short time by one apparatus. The lighting device for guiding the next insertion of the terminal can be lighted with the control unit by the signal from the detecting means.

A method of checking terminal lock comprises the steps of securing a connector housing at a housing set portion, inserting a terminal connected with an electric wire into the connector housing, locking the terminal in the connector housing, pushing the housing set portion in a direction of inserting the terminal by push means, and pulling the electric wire in a direction of extracting the terminal for checking terminal lock.

According to above steps, the connector housing secured at the housing set portion is moved together with the housing set portion against pushing force of the push means by pulling the electric wire led from the connector housing in the direction of extracting the terminal. If the terminal is locked completely in the connector housing, the terminal is moved together with the connector housing and the pushing force as checking force for checking terminal lock is loaded on the terminal. If the terminal is not locked completely, the terminal is moved against the connector housing in the direction of extracting the terminal by the pushing force and a defect of terminal lock is detected by an operator hand.

The method of checking terminal lock is further specified in method of checking terminal lock mentioned above by comprising a step of indicating whether or not pushing force of the push means reaches checking force for checking terminal lock.

According to above step, the operator can recognize that checking terminal lock is performed with accurate pulling force. Thereby, the terminal is prevented from unnecessary further pulling.

The above and other objects and features of this invention will become more apparent from the following description taken in conjunction with the accompanying drawings.

### BRIEF DESCRIPTION OF THE DRAWINGS

FIG. 1 is a partially sectional front view of an embodiment of an apparatus for checking terminal lock according to this invention;

FIG. 2 is a partially sectional side view of the apparatus for checking terminal lock in FIG. 1; and

FIG. 3 is a plan view (top view) of the apparatus for checking terminal lock in FIG. 1.

### DESCRIPTION OF THE PREFERRED EMBODIMENT

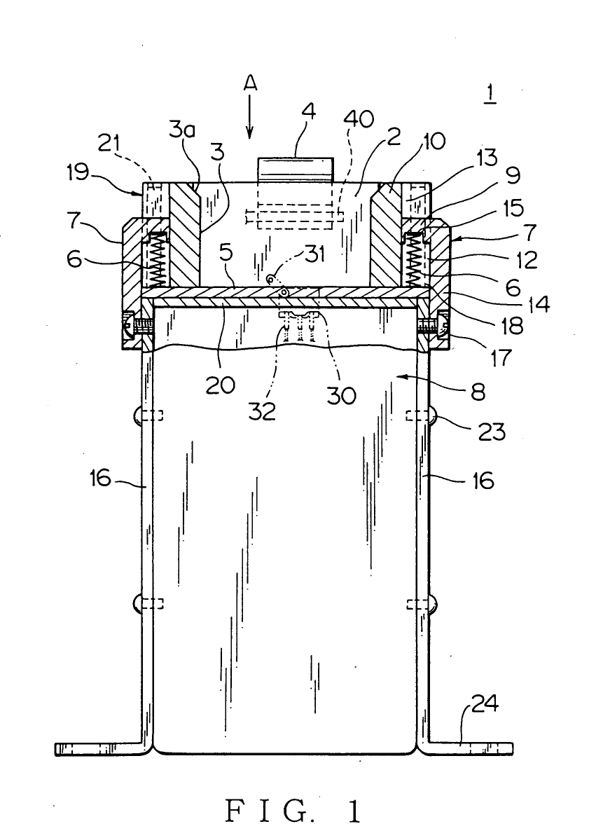

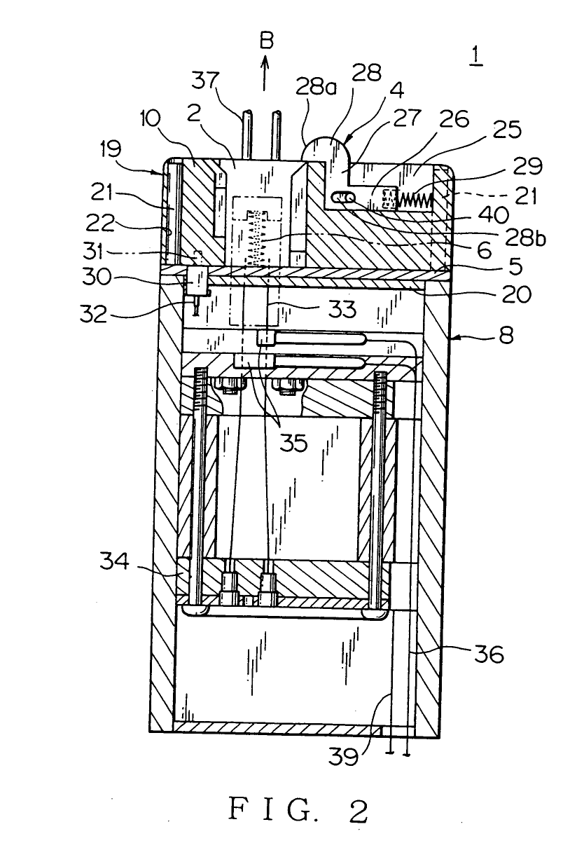

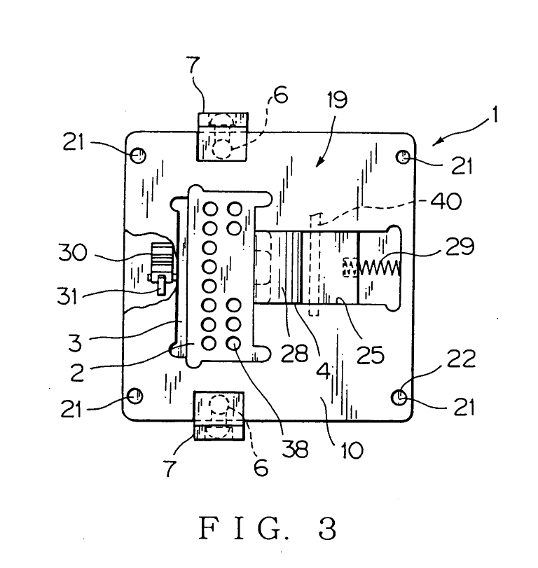

A first embodiment of an apparatus for checking terminal lock according to this invention is shown in FIG. 1-3. FIG. 1 is a partially sectional front view of the embodiment. FIG. 2 is a partially sectional side view of the embodiment. FIG. 3 is a plan view (top view) corresponding to FIG. 2.

The apparatus for checking terminal lock 1 includes an opening of housing insertion 3 for inserting a connector housing 2 made of synthetic resin, a lock member 4 for locking the connector housing 2 to prevent the connector housing from slipping out of the opening of housing insertion 3, a movable base plate 5 being also as a bottom wall of the opening of housing insertion 3, a coil spring 6 (push means) for pushing the movable base plate 5 in a direction of housing insertion, i.e. a direction of inserting terminals, as shown by an arrow A, a stopper 7 for holding a fixed end of the coil spring 6, and a main body 8 which the stopper 7 is fixed on.

The opening of housing insertion 3 has an opening 3a (FIG. 1) at the top thereof and the connector housing 2 is inserted downwardly from upper side of the opening of housing insertion 3 into the opening of housing insertion 3. The movable base plate 5 is disposed horizontally and formed to have almost same dimensions of width and depth as those of the main body 8. A top surface of the movable base plate 5 forms a bottom surface of the opening of housing insertion 3. Bottom ends of a pair of coil springs 6 disposed respectively at right and left sides of the main body 8 abut on the right and left sides of the top surface of the movable base plate 5. Top ends of the pair of coil springs 6 abut respectively on a hook 9 (FIG. 1) at the top of each stopper 7. On this condition, each coil spring 6 is in small spring travel.

The opening of housing insertion 3 is formed vertically in a housing set block 10. Each coil spring is received into a cylindrical receiving space in the housing set block 10. The receiving space communicates to a long slit cutout 12 (FIG. 1) and an upper cutout 13 (FIG. 1) formed vertically at the housing set block 10 for passing the hook 9 of the stopper 7 therethrough.

The stopper 7 has a vertical long portion 14 (FIG. 1) and the hook 9 extending inward horizontally at the top end of the long portion 14. The hook 9 is provided at a bottom surface thereof with a counter bore 15 (FIG. 1) for receiving and positioning the top end of the coil spring 6. The long portion 14 is provided at a low end thereof with a through hole for fixing the stopper 7 on a cover 16 (FIG. 1) of the main body 8 with a screw 17. The stopper is formed from the bottom surface of the hook 9 along a lengthwise of the long portion 14 with a guide groove 18 (FIG. 1) for guiding the movable base plate 5 to move vertically. The low ends of the long portions 14 are fixed on outer surfaces of the covers 16 as right/left side walls of the main body 8 and the hooks 9 are disposed in the upper cutouts 13 communicating to the receiving space of the housing set block 10.

The housing set block 10 is fixed on the movable base plate 5 as capable to move upward freely together with the movable base plate 5 against pushing force of the coil spring 6. A housing set portion 19 is structured at least by the housing set block 10 and the movable base plate 5. The housing set portion 19 can be formed in one piece integrally with the housing set block 10 and the movable base plate 5.

A plurality of guide bars 21 (guide member), four bars in this embodiment, is fixed on a top wall 20 of the main body 8 so as to project upward from the top wall 20. Respective guide bars 21 are engaged slidably with guide holes 22 disposed vertically at the housing set block 10.

The right and left covers 16 (FIG. 1) are fixed on the main body 8 with screws 23 (FIG. 1). Brackets 24 (FIG. 1) extend outward perpendicularly at low ends of the covers 16. The brackets 24 are fixed on a workbench (not shown) with screws.

A lock member 4 (FIG. 2) for preventing the connector housing 2 from going out of the opening of housing insertion 3 is disposed slidably in a horizontal cutout 25 of the housing block 10 to move horizontally. The lock member 4 includes a base portion 26 slidable along a bottom surface of the cutout 25, a standing portion 27 extending upward from the front end of the base portion 26 and a hook portion 28 extending horizontally from the top of the standing portion 27. The hook portion 28 has a curved housing guide surface 28a. The hook portion 28 also performs an operating portion for unlock.

A horizontal oval slit 28b (FIG. 2) is provided at the base portion 26 of the lock member 4. A horizontal guide bar 40 is inserted into the oval hole 28b and ends of the guide bar 40 are fixed on the housing set block 10. A coil spring 29 is disposed at a rear end of the base portion 26 so as to push the lock member 4 forward, i.e. in a direction of locking.

The hook portion 28 of the lock member 4 is positioned along the top surface of the housing set block 10 to face onto the opening 3a of the opening of housing insertion 3. Thereby, the hook portion 28 abuts on the top surface of the connector housing 2, when the connector housing 2 is inserted into the opening of housing insertion 3, i.e. a rear surface of wire leading side of the connector housing 2, to prevent the connector housing from going out. The lock member 4 can be unlocked easily by pushing the lock member 4 backward against the pushing force of the spring. The lock member 4 can be designed not only in this embodiment but also in any various structures capable to prevent the connector housing 2 from going out.

A detective switch 30 (detecting means) is disposed at the main body 8 correspondingly to the movable base plate 5 of the housing set portion 10. Motion of the movable base plate 5 is detected by the detective switch 30. The detective switch 30 has a lever type moving element 31 pushed upward by a spring. The moving element 31 can rotate freely up and down by contacting the top thereof with the bottom surface of the moving base plate 5 in accordance with up-and-down motion of the moving base plate 5.

The detective switch 30 is connected with a not-shown lamp or a buzzer. When the moving element 31 is moved upward in a predetermined travel (checking terminal lock is passed), the lamp may be turned on. When the moving element 31 is not moved in a predetermined travel, the buzzer sounds to show failed. The detective switch 30 may be joined with a lead wire 32 led outward from the main body 8 to be connected with a not-shown control device. Thereby, it is designed that the next terminal can be guided for insertion in the only case when the travel meets the predetermined value.

Contact probes 33 (FIG. 2) projecting the points thereof into the opening of housing insertion 3 for continuity test are disposed in the main body 8 correspondingly to the number and positions of terminal receiving sections 38 (FIG. 3) of the connector housing 2. The contact probes 33 are joined respectively with lead wires 39 (FIG. 2) led outward to be connected with the control unit (not shown). The contact probes 33 are held on a hold block 34 (FIG. 2) which can be mounted and dismounted with screws in the main body 8 correspondingly to types of the connectors. The housing set portion 19 can be also mounted and dismounted in the main body 8 correspondingly to types of the connectors. The apparatus for checking terminal lock 1 added with the contact probes 33 for continuity test performs as an apparatus for checking terminal lock and continuity test.

Lighting devices 35 (light emitting diodes, FIG. 2) are disposed in the main body 8 for guiding the terminals for insertion correspondingly to the number and positions of terminal receiving sections 38 of the connector housing 2. The lighting devices 35 are connected with the outside control unit by lead wires 36. The lighting device 35 indicates a inserting position of the terminal for an operator by illuminating a required terminal receiving section 38 from a bottom side of the connector housing 2. The lighting devices 35 are illuminated by control of the control unit in which a sequence of terminal insertion or relation between the terminal receiving sections 38 and the terminals (to be inserted in which terminal receiving section 38) is stored previously. The aforesaid apparatus for checking terminal lock 1 further added with the lighting devices 35 for guiding the terminal for insertion performs as an apparatus for guiding terminal insertion, checking terminal lock and continuity test.

A method of using the aforesaid apparatus for checking terminal lock (the apparatus for guiding insertion of terminal, checking terminal lock and continuity test), i.e. a method of checking terminal lock will be described following.

Firstly, the connector housing 2 is inserted into the opening of housing insertion 3. At the time, the front end of the connector housing 2 abuts on the curved housing guide surface 28a (FIG. 2) of the hook portion 28 of the lock portion 4 so as to push the lock portion 4 to be slid backward automatically. When the connector housing 2 is inserted completely, the lock portion 4 is moved back by the pushing force of the spring 29 and locks the connector housing 2. Thus, the connector housing 2 can be secured easily and quickly.

The points of the contact probes 33 for continuity test penetrate into the connector hosing 2.

The terminals of electric wires 37 with a terminal are inserted into the required terminal receiving sections 38 of the connector housing 2 from upper side. The terminals can be inserted securely by illumination of the lighting devices 35 (FIG. 2). The terminals are locked with flexible lances (not shown) in terminal receiving sections and simultaneously the front ends of the terminals contact with the points of the contact probes 33 for continuity test. Thereby, the continuity test of the electric wires 37 with a terminal can be performed with a control unit for continuity test (not shown).

The continuity test is performed on condition that terminals at the other ends of the electric wires are previously inserted into the other connector housing (not shown) and the other connector is set in a continuity test tool (not shown), or on condition that terminals at the other ends of the electric wires are inserted into a connector housing of the other apparatus for checking terminal lock and continuity test (not shown).

After one terminal of one electric wire 37 with a terminal is inserted into the connector housing 2 in the housing set portion 19 shown in FIG. 1-3, the one electric wire 37 is pulled in an opposite direction of inserting the terminal, i.e. in a direction of extracting the terminal shown with an arrow B by an operator. Thereby, pulling force of the terminal is transmitted to the connector housing 2, and the connector housing 2 is moved upward along the guide bar 21 against the pushing force of the coil spring 6 together with the housing set portion 19, i.e. the housing set block 10 and the movable base plate 5. When the terminal is locked completely and the moving travel of the terminal meets the required value, the detective switch 30 detects that and pass of checking terminal lock is indicated by lighted lamp.

The required value of the moving travel means a moving travel for compressing the coil spring 6 so as to supply a predetermined force for checking terminal lock corresponding to the terminal type. The force for checking terminal lock is determined by multiplying the spring constant and the moving travel. Thereby, dispersion of the pulling force by operators is eliminated so that checking terminal lock can be performed securely by any operators.

When checking terminal lock is passed, by stopping pulling the electric wire 37, the housing set portion 19 is returned to an initial position together with the connector housing 2 by a restoring force of the coil spring 6 in a direction of spring extension. Next terminal is inserted into the connector housing 2 and checking terminal lock is performed by the same way. The housing set portion 19 is guided along the guide bar 21 so as to move smoothly. By the guide bar 21, the terminal receiving sections 38 of the connector housing are positioned securely correspondingly to the contact probes 33 for continuity test and the lighting devices 35 for guiding terminal insertion in the main body 8.

Checking terminal lock for two terminals can be performed at the same time by pulling two electric wires 37 with a terminal with both hands on condition of doubling the checking force of checking terminal lock. When the moving travel of the terminal meets the required value and the detective switch 30 detects that, the control unit (not shown) to detect the signal of the detective switch 30 can light the lighting device 35 at the next terminal receiving section 38 or indicate a position of the next inserting electric wire 37 with a terminal in a rack (not shown) for electric wires by lighting.

In this embodiment, the checking force for the electric wire 37 is generated by the coil spring 6 as push means. Instead of the coil spring, push means such as a helical extension spring, an elastic member like a rubber, an air cylinder and a dead weight can be used to push the housing set portion 19 together with the connector housing 2 in the opposite direction of pulling the electric wires, i.e. in the direction of inserting terminals.

In this embodiment, position of setting the connector housing 2 is located eccentrically from the center of the housing set block 10. By locating the connector housing 2 on the center of the housing set block, the housing set block 10 can be slid more smoothly against the guide bar 21. In this case, the pair of the coil springs 6 as push means are disposed symmetrically at the both of right/left sides of the connector housing 2 so that the performance is substantially the same in use.

The coil springs 6 are preferably disposed on a line passing through the center of the connector housing 2. When four coil springs 6 are disposed, the coil springs are preferably on two cross line passing through the center of the connector housing 2.

Instead of the guide bar 21, a guide groove can be provided on a wall (not shown) disposed vertically at the main body 8 so as to engage the housing set portion 19 slidably in an up-and-down direction with the guide groove. The detective switch 30 is not limited in the stroke type, and a laser-type detective switch and a contactless switch can be used. A lock arm, a lock pin and a lock lever can be applied for the lock member 4.

In this embodiment, the housing set portion 19 is moved by means of pulling the electric wire 37 on condition of holding the main body 8. By holding the electric wire 37 with a clamp and pulling the main body 8 to be moved, the housing set portion 19 can be moved relatively in the direction of pulling the electric wire.

Although the present invention has been fully described by way of examples with reference to the accompanying drawings, it is to be noted that various change and modifications can be made with the scope of the present invention as defined by the following claims.

What is claimed is:

1. An apparatus for checking terminal lock comprising:
a main body;
a housing set portion for securing a connector housing, said housing set portion being disposed at said main body so as to move freely in a direction of inserting and extracting a terminal; and
push means for pushing said housing set portion in the direction of inserting the terminal.

2. The apparatus for checking terminal lock according to claim 1, further comprising detecting means for detecting whether or not pushing force of said push means reaches equal to checking force of checking terminal lock.

3. The apparatus for checking terminal lock according to claim 1 or 2, wherein said push means is a coil spring.

4. The apparatus for checking terminal lock according to claim 3, further comprising a stopper supporting said coil spring at one end thereof and being fixed on said main body at the other end thereof.

5. The apparatus for checking terminal lock according to claim 1, further comprising a guide member for guiding said housing set portion in the direction of inserting and extracting the terminal.

6. The apparatus for checking terminal lock according to claim 1, further comprising a contact probe for testing continuity of said terminal at said main body.

7. The apparatus for checking terminal lock according to claim 1, further comprising a lighting device provided at said main body for guiding the insertion of said terminal into a terminal receiving section of said connector housing.

8. A method of checking terminal lock comprising the steps of:
securing a connector housing at a housing set portion;
inserting a terminal connected with an electric wire into said connector housing;
locking said terminal in said connector housing;
pushing said housing set portion in a direction of inserting said terminal by push means; and
pulling said electric wire in a direction of extracting said terminal for checking terminal lock.

9. The method of checking terminal lock according to claim 8, further comprising a step of indicating whether or not pushing force of said push means reaches checking force for checking terminal lock.
